(19) United States
(12) Patent Application Publication
(10) Pub. No.: US 2021/0091340 A1
(43) Pub. Date: Mar. 25, 2021

(54) DISPLAY PANEL AND DISPLAY DEVICE

(71) Applicant: WUHAN CHINA STAR OPTOELECTRONICS SEMICONDUCTOR DISPLAY TECHNOLOGY CO., LTD., Wuhan (CN)

(72) Inventor: Jiajia SUN, Wuhan (CN)

(73) Assignee: WUHAN CHINA STAR OPTOELECTRONICS SEMICONDUCTOR DISPLAY TECHNOLOGY CO., LTD., Wuhan (CN)

(21) Appl. No.: 16/641,659

(22) PCT Filed: Nov. 15, 2019
(86) PCT No.: PCT/CN2019/118865

§ 371 Date: Feb. 25, 2020

(30) Foreign Application Priority Data
Sep. 25, 2019 (CN) 201910911090.2

(51) Int. Cl. H01L 51/52; H01L 27/32

(52) U.S. Cl. CPC H01L 51/5275; H01L 27/3244; H01L 51/5253

(57) ABSTRACT

The present invention provides a display panel and a display device including a light-emitting layer and a light extraction layer disposed on a side of the light-emitting layer. A light-exiting surface is disposed on a side of the light extraction layer away from the light-emitting layer. The light-exiting surface includes at least one curved surface and is configured to increase light transmittance of light in the light-exiting surface. When the light-exiting surface includes a plurality of curved surfaces, the plurality of curved surfaces are connected to each other and form a continuous light-exiting surface.

### FIELD OF INVENTION

The present invention is related to the field of display technology, and specifically to a display panel and a display device.

### BACKGROUND OF INVENTION

Currently, compared to liquid crystal display (LCD) technology, organic light-emitting diode (OLED) display technology has advantages such as self-luminescence, wide viewing angles, almost infinitely high contrast, low power consumption, and extremely fast response times.

However, because of total reflection inside an OLED display panel, as shown in FIG. 1, when light enters a second film layer 02 with a lower refractive index from a light extraction layer 01 with a higher refractive index, a refraction angle θ2 is greater than an incidence angle θ1. When the incidence angle θ1 corresponding to the light is large enough, as shown in FIG. 2, a corresponding refraction angle θ2 increases to 90°, so that any light with an incidence angle greater than θ1 cannot pass through the second film layer 02. This ultimately causes low light transmittance of light in the OLED display panel, which causes display brightness of the OLED display panel to be low and also reduces light utilization of the OLED display panel.

Therefore, it is necessary to provide a display panel and a display device that can increase display brightness of the OLED display panel and light utilization of the OLED display panel to improve image quality of the OLED display panel.

### SUMMARY OF INVENTION

A purpose of the present invention is to provide a display panel and a display device that can solve problems of low display brightness of an organic light-emitting diode (OLED) display panel and low light utilization of the OLED display panel in the prior art by disposing at least one curved surface on a light-exiting surface of a light extraction layer.

In order to solve the above problems, the present invention provides technical solutions as follows.

An embodiment of the present invention provides a display panel including:

a light-emitting layer configured to emit light; and

a light extraction layer disposed on a side of the light-emitting layer and configured to transmit the light, wherein the light extraction layer includes:

a light-exiting surface disposed on a side of the light extraction layer away from the light-emitting layer, wherein the light-exiting surface includes at least one curved surface, and the light is refracted by the light-exiting surface.

In an embodiment, when the light-exiting surface includes a plurality of curved surfaces, the plurality of curved surfaces are connected to each other and form a continuous light-exiting surface.

In an embodiment, highest points of the plurality of curved surfaces are on a same horizontal plane, and lowest points of the plurality of curved surfaces are on a same horizontal plane.

In an embodiment, shapes of the plurality of curved surfaces are same or different.

In an embodiment, the shapes of the plurality of curved surfaces include at least one of an upper hemispherical surface or a lower hemispherical surface.

In an embodiment, a shape of a projection of the at least one curved surface on the light extraction layer includes circular, rhombic, or square.

In an embodiment, material of the light extraction layer includes a nano material.

In an embodiment, a thickness of the light extraction layer is not less than 2 nanometers and not greater than 20 nanometers.

In an embodiment, the display panel further includes a protective layer disposed on the side of the light extraction layer away from the light-emitting layer, wherein material of the protective layer includes lithium fluoride.

In an embodiment, a refractive index of the light extraction layer is greater than a refractive index of the protective layer.

An embodiment of the present invention further provides a display device including a display panel. The display panel includes:

a light-emitting layer configured to emit light; and

a light extraction layer disposed on a side of the light-emitting layer and configured to transmit the light, wherein the light extraction layer includes:

a light-exiting surface disposed on a side of the light extraction layer away from the light-emitting layer, wherein the light-exiting surface includes at least one curved surface, and the light is refracted by the light-exiting surface.

In an embodiment, when the light-exiting surface includes a plurality of curved surfaces, the plurality of curved surfaces are connected to each other and form a continuous light-exiting surface.

In an embodiment, highest points of the plurality of curved surfaces are on a same horizontal plane, and lowest points of the plurality of curved surfaces are on a same horizontal plane.

In an embodiment, shapes of the plurality of curved surfaces are same or different.

In an embodiment, the shapes of the plurality of curved surfaces include at least one of an upper hemispherical surface or a lower hemispherical surface.

In an embodiment, a shape of a projection of the at least one curved surface on the light extraction layer includes circular, rhombic, or square.

In an embodiment, material of the light extraction layer includes a nano material.

In an embodiment, a thickness of the light extraction layer is not less than 2 nanometers and not greater than 20 nanometers.

In an embodiment, the display panel further includes a protective layer disposed on the side of the light extraction layer away from the light-emitting layer, wherein material of the protective layer includes lithium fluoride.

In an embodiment, a refractive index of the light extraction layer is greater than a refractive index of the protective layer.

The present invention provides the display panel and the display device including the light-emitting layer and the light extraction layer disposed on the side of the light-emitting layer. The light-exiting surface is disposed on the side of the light extraction layer away from the light-emitting layer. By disposing at least one curved surface on the light-exiting surface and determining a proper curvature of the at least one curved surface, the light emitted from the light-emitting layer in most directions can be prevented from being totally reflected on the light-exiting surface, which increases light utilization of the OLED display panel to improve image quality of the OLED display panel.

### DESCRIPTION OF DRAWINGS

The present invention is further described below with reference to drawings. It should be explained that the drawings described below are only for some embodiments of the present invention, and other drawings may be obtained by those skilled in the art based on these drawings without creative efforts.

FIG. 1 is a schematic diagram of a light path of a display panel in the prior art.

FIG. 2 is another schematic diagram of the light path of the display panel in the prior art.

FIG. 3 is a first cross-sectional diagram of a display panel according to an embodiment of the present invention.

FIG. 4 is a second cross-sectional diagram of the display panel according to an embodiment of the present invention.

FIG. 5 is a third cross-sectional diagram of the display panel according to an embodiment of the present invention.

FIG. 6 is a fourth cross-sectional diagram of the display panel according to an embodiment of the present invention.

FIG. 7 is a fifth cross-sectional diagram of the display panel according to an embodiment of the present invention.

FIG. 8 is a sixth cross-sectional diagram of the display panel according to an embodiment of the present invention.

FIG. 9 is a three-dimensional view of a light-exiting surface according to an embodiment of the present invention.

FIG. 10 is a schematic diagram of a geometric figure according to an embodiment of the present invention.

FIG. 11 a three-dimensional view of another light-exiting surface according to an embodiment of the present invention.

FIG. 12 is a seventh cross-sectional diagram of the display panel according to an embodiment of the present invention.

FIG. 13 is an eighth cross-sectional diagram of the display panel according to an embodiment of the present invention.

FIG. 14 is a ninth cross-sectional diagram of the display panel according to an embodiment of the present invention.

FIG. 15 is a schematic diagram of a projection of the light-exiting surface on a light extraction layer according to an embodiment of the present invention.

FIG. 16 is a schematic diagram of a projection of another light-exiting surface on the light extraction layer according to an embodiment of the present invention.

FIG. 17 is a schematic diagram of a projection of yet another light-exiting surface on the light extraction layer according to an embodiment of the present invention.

FIG. 18 is a tenth cross-sectional diagram of the display panel according to an embodiment of the present invention.

FIG. 19 is an eleventh cross-sectional diagram of the display panel according to an embodiment of the present invention.

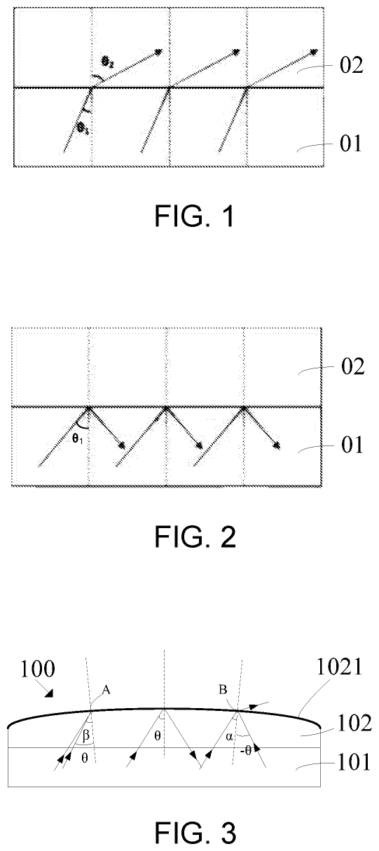

### DETAILED DESCRIPTION OF PREFERRED EMBODIMENTS

To further explain the technical means and effect of the present invention, the following refers to embodiments and drawings for detailed description. Obviously, the described embodiments are only for some embodiments of the present invention, instead of all embodiments. Based on the embodiments of the present invention, all other embodiments obtained by those skilled in the art without creative work fall into a protection scope of the present invention.

The specification and claims do not intend to distinguish between components that differ in name. Instead the components are distinguished based on their functions. As mentioned throughout the specification and claims, the term “include” is used in an open-ended fashion, and thus should be interpreted to mean “including, but not limited to”.

Terms mentioned in the present invention, such as “upper,” “lower,” “side,” etc., should be construed to refer to the orientation as then described or as shown in the drawings. These terms are just used to facilitate and simplify descriptions of embodiments of the present invention, rather than indicating or implying that any mentioned component must have a particular orientation, or be constructed or operated in a particular orientation, and hence cannot be understood as limitations to the present disclosure.

It should be noted that terms such as “height direction,” “width direction,” and “length direction” define a length, a width, and a length according to a conventional definition of a placement position of a structure of the drawing. For example, the height direction includes any direction along two ends of a line corresponding to a height of the structure in the drawing.

In addition, it should be explained that the drawings only provide structures and steps that are closely related to the present invention and omit some details that are not related to the present invention. Its purpose is to simplify the drawings and make the present invention obvious and not to indicate a device and a method are exactly same as those in the drawings, which should not be regarded as limitations of the device and the method in actual implements.

The present invention provides a display device including a display panel as shown in FIGS. 3-8, 12-14, 18, and 19.

In an embodiment as shown in FIGS. 3-8 and 12-14, the display panel 100 includes a light-emitting layer 101 and a light extraction layer 102 disposed on a side of the light-emitting layer 101. The light-emitting layer 101 is configured to emit light. The light extraction layer 102 is configured to transmit light.

The light extraction layer 102 includes a light-exiting surface 1021. The light-exiting surface 1021 is disposed on a side of the light extraction layer 102 away from the light-emitting layer 101. The light-exiting surface 1021 includes at least one curved surface. The light-exiting surface 1021 is configured to increase light transmittance of the light in the light-exiting surface 1021. When the light-exiting surface 1021 includes a plurality of curved surfaces, the plurality of curved surfaces are connected to each other and form a continuous light-exiting surface 1021.

Understandably, the “continuous” means that the light-exiting surface 1021 is a surface without a gap and is not limited to the light-exiting surface 1021 being smooth at any point, or a slope of a tangent line at any point being same in any direction. For example, a junction between two curved surfaces does not need to be smooth. If the junction between each smooth curved surface is smooth, the present invention temporarily defines a situation that the light-exiting surface 1021 includes one curved surface.

In an embodiment, the light-exiting surface 1021 can be formed by techniques such as etching or nanoimprinting.

It should be noted that a refractive index of the light extraction layer 102 is greater than a refractive index of air, and is greater than a refractive index of film layers above the light extraction layer 102, which means that an incidence angle of the light at the light-exiting surface 1021 is smaller than a refraction angle thereof. Therefore, a total reflection phenomenon may occur on the light-exiting surface 1021, which means that the incidence angle of the light at the light-exiting surface 1021 is greater than a critical angle corresponding to the total reflection, and unrefracted light is emitted from the light-exiting surface 1021.

In an embodiment, the refractive index of the light extraction layer 102 can be greater than a refractive index of the light-emitting layer 101. Furthermore, the refractive index of the light extraction layer 102 can be greater than 2.

When the light-exiting surface 1021 is a curved surface, understandably, as shown in FIG. 9, the light-exiting surface 1021 can be a trajectory S formed by a continuous and smooth curve L in a plane continuously moving in space. The continuous movement indicates that a direction of the movement is continuously changing, which means that trends of movement directions on two sides of a certain place must be same. For ease of understanding, it can be assumed here that the continuous and smooth curve L is a curve formed by cutting the light-exiting surface 1021 of the light extraction layer 102 in a direction parallel to a length of the display panel 100. Understandably, the direction of the movement is a direction parallel to a width of the display panel 100. For specific embodiments, please refer to FIGS. 3 to 8. Of course, the direction of the movement herein may not be limited to one direction, which means that the direction of the movement can include multiple directions.

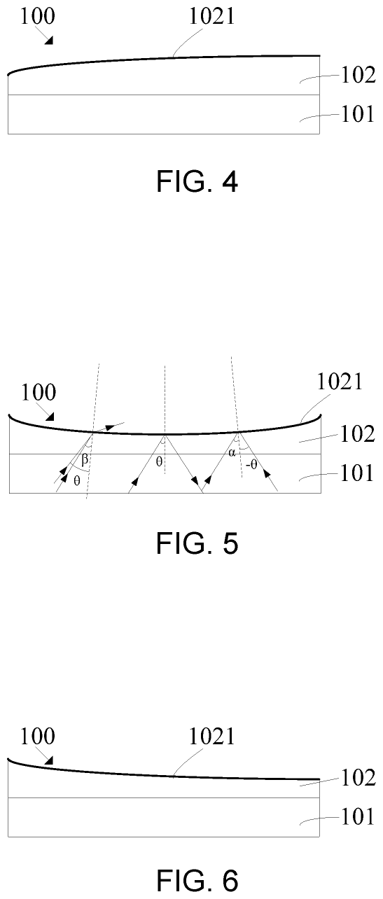

In an embodiment, as shown in FIGS. 3 to 4, the light-exiting surface 1021 can be a convex curved surface.

In an embodiment, as shown in FIG. 3, the light-exiting surface 1021 is an axisymmetric convex curved surface. If an angle formed with a height direction of the display panel 100 is θ, light in this direction is totally reflected at a highest point of the convex curved surface. Any incidence angle α of light in a direction on a right side of the highest point is less than an incidence angle θ corresponding to the total reflection, so that the light in the direction can be refracted from the right side of the highest point. However, an incidence angle β of light in a direction on a left side of the highest point is greater than the incidence angle θ corresponding to the total reflection, so that the light in the direction cannot be refracted from the left side of the highest point.

Comparing the light-exiting surface 1021 of the convex curved surface in FIG. 3 to a light-exiting surface of an ordinary flat surface, for light in a direction that the total reflection occurs at the highest point of the convex curved surface, there is a 50% probability of light refracting from the light-exiting surface 1021. For example, light in a direction at the angle θ from the height direction of the display panel 100 can be refracted from a right side of the light-exiting surface 1021, and light in a direction at the angle −θ from the height direction of the display panel 100 can be refracted from a left side of the light-exiting surface 1021.

It should be noted that the angle of the light emitted from a left side of the display panel 100 to the light-exiting surface 1021 is a positive angle, and the angle of the light emitted from a right side of the display panel 100 to the light-exiting surface 1021 is a negative angle.

Understandably, for light in a direction that the total reflection angle occurs at a first point A on the left side of the highest point of the convex curved surface, when a curvature of the convex curved surface is within a certain range, the light in this direction is emitted from the first point A to the right side, and an absolute value of a corresponding incidence angle is less than θ, which means that all corresponding lights can be refracted. Similarly, for light in a direction that the total reflection angle occurs at a second point B on the right side of the highest point of the convex curved surface, when the curvature of the convex curved surface is within the certain range, the light in this direction is emitted from the second point B to the left side, and the absolute value of the corresponding incidence angle is less than θ, which means that all corresponding lights can be refracted.

In summary, for the light-exiting surface 1021 of the convex curved surface in FIG. 3, light in a direction at an absolute value of an angle that is not greater than 8 with respect to the height direction of the display panel 100 can be refracted from the light-exiting surface 1021 with a probability of not less than 50%. Understandably, light in another direction can be refracted from the light-exiting surface 1021 with a probability of less than 50%.

In an embodiment, as shown in FIG. 4, the light-exiting surface 1021 configures right and left ends of the display panel 100 as a highest horizontal plane and a lowest horizontal plane, respectively. A smooth transition in a middle is formed into a convex curved surface, and a corresponding relationship between the highest horizontal plane and the lowest horizontal plane and the right and left ends is not limited. A difference between the embodiment in FIG. 4 and the embodiment in FIG. 3 is that the convex curved surface corresponding to the light-exiting surface 1021 is not an axisymmetric figure. As shown in FIG. 4, the highest horizontal plane and the lowest horizontal plane are respectively disposed corresponding to the right and left ends. According to the above analysis, the light in the direction at the angle −θ with respect to the height direction of the display panel 100 is totally reflected at the highest point of the convex curved surface and can be refracted from the left side of the light-exiting surface 1021, which means that the light on the light-exiting surface 1021 in the −θ direction can be refracted from any position on the light-exiting surface 1021. However, the light in the direction at the angle θ with respect to the height direction of the display panel 100 can be only refracted from the right side of the light-exiting surface 1021, which means that the light in the 8 direction cannot be refracted from the light-exiting surface 1021. On this basis, furthermore, the light in the direction at the absolute value of the angle that is less than θ with respect to the height direction of the display panel 100 can be refracted from any position on the light-exiting surface 1021.

In summary, for the light-exiting surface 1021 of the convex curved surface in FIG. 4, light in a direction at an angle that is not less than −θ and not greater than 0° with respect to the height direction of the display panel 100 can be refracted from any position on the light-exiting surface 1021. Understandably, some light in another direction can be refracted from the light-exiting surface 1021. Light in a direction at an angle that is not less than θ with respect to the height direction of the display panel 100 cannot be refracted from the light-exiting surface 1021. Understandably, some light in another direction can be refracted from the light-exiting surface 1021.

Understandably, when the highest horizontal plane and the lowest horizontal plane are respectively disposed corresponding to the right and left ends, a reference can also be made to a related description of FIG. 4, which can be understood as front and rear relationships of the display panel 100 rotating 180° in a horizontal direction.

In an embodiment, as shown in FIGS. 5 to 6, the light-exiting surface 1021 can be a concave curved surface.

In an embodiment, as shown in FIG. 5, the light-exiting surface 1021 is an axisymmetric concave curved surface. If an angle formed with a height direction of the display panel 100 is θ, light in this direction is totally reflected at a highest point of the concave curved surface. Any incidence angle β of light in a direction on a left side of the highest point is less than an incidence angle θ corresponding to the total reflection, so that the light in the direction can be refracted from the left side of the highest point. However, an incidence angle α of light in a direction on a right side of the highest point is greater than the incidence angle θ corresponding to the total reflection, so that the light in the direction cannot be refracted from the right side of the highest point.

Similarly, referring to a related description of FIG. 3, it can be obtained that for the light-exiting surface 1021 of the concave curved surface in FIG. 5, light in a direction at an absolute value of an angle that is not greater than θ with respect to the height direction of the display panel 100 can be refracted from the light-exiting surface 1021 with a probability of not less than 50%. Understandably, light in another direction can be refracted from the light-exiting surface 1021 with a probability of less than 50%.

Understandably, because the light-emitting layer 101 emits light in various directions, and the light-exiting surfaces 1021 in FIGS. 3 and 5 are turned 180° to form curved surfaces corresponding to each other, therefore, the light extraction layers 102 in FIGS. 3 and 5 have a same contribution effect on light extraction of light emitted from the light-emitting layer 101.

In an embodiment, as shown in FIG. 6, the light-exiting surface 1021 configures left and right ends of the display panel 100 as a highest horizontal plane and a lowest horizontal plane, respectively. A smooth transition in a middle is formed into a concave curved surface, and a corresponding relationship between the highest horizontal plane and the lowest horizontal plane and the left and right ends is not limited. A difference between the embodiment in FIG. 6 and the embodiment in FIG. 5 is that the concave curved surface corresponding to the light-exiting surface 1021 is not an axisymmetric figure. As shown in FIG. 6, the highest horizontal plane and the lowest horizontal plane are respectively disposed corresponding to the left and right ends. According to the above analysis, the light in the direction at the angle θ with respect to the height direction of the display panel 100 is totally reflected at the highest point of the concave curved surface and can be refracted from the left side of the light-exiting surface 1021, which means that the light in the θ direction can be refracted from any position on the light-exiting surface 1021. However, the light in the direction at the angle −θ with respect to the height direction of the display panel 100 can be only refracted from the right side of the light-exiting surface 1021, which means that the light in the −θ direction cannot be refracted from the light-exiting surface 1021. On this basis, furthermore, the light in the direction at the absolute value of the angle that is less than θ with respect to the height direction of the display panel 100 can be refracted from any position on the light-exiting surface 1021.

In summary, for the light-exiting surface 1021 of the concave curved surface in FIG. 6, light in a direction at an angle that is not less than 0° and not greater than θ with respect to the height direction of the display panel 100 can be refracted from any position on the light-exiting surface 1021. Light in a direction at an angle that is not greater than −θ with respect to the height direction of the display panel 100 cannot be refracted from the light-exiting surface 1021. Understandably, some light in another direction can be refracted from the light-exiting surface 1021.

Understandably, when the highest horizontal plane and the lowest horizontal plane are respectively disposed corresponding to the left and right ends, a reference can also be made to a related description of FIG. 6, which can be understood as front and rear relationships of the display panel 100 rotating 180° in a horizontal direction.

Understandably, because the light-emitting layer 101 emits light in various directions, and the light-exiting surfaces 1021 in FIGS. 4 and 6 are turned 180° to form curved surfaces corresponding to each other, therefore, the light extraction layers 102 in FIGS. 4 and 6 have a same contribution effect on light extraction of light emitted from the light-emitting layer 101.

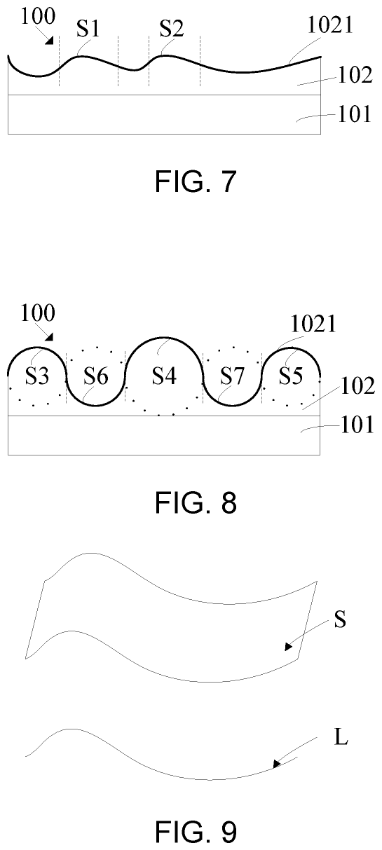

In an embodiment, as shown in FIGS. 7 and 8, the light-exiting surface 1021 can be a convex and concave curved surface, and the convex and concave curved surface indicates that the light-exiting surface 1021 is a continuous and smooth curved surface having both convex and concave surfaces.

In an embodiment, as shown in FIG. 7, the light-exiting surface 1021 includes a plurality of convex surfaces and concave surfaces. A shape of each of the plurality of convex surfaces can be different, and a shape of each of the plurality of concave surfaces can be different. Each of the plurality of convex surfaces can be, but is not limited to, an axisymmetric figure, and each of the plurality of concave surfaces can be, but is not limited to, an axisymmetric figure. Comparing the embodiment of FIG. 7 and the embodiments of FIGS. 3 to 6, a difference is that the light-exiting surface 1021 includes the convex and concave surfaces with various curvatures.

For example, for convex curved surfaces S1 and S2 in FIG. 7, a curvature of each of the convex curved surfaces is different, and for a same convex curved surface, the curvature can be a fixed value or can include a plurality of different values. In order to form a continuous and smooth light-exiting surface 1021, for the convex curved surfaces S1 and S2 including different curvatures, the curvature can satisfy a changing trend of first increasing and then decreasing. Similarly, for the concave curved surfaces in FIG. 7, the curvature can also satisfy the changing trend of first increasing and then decreasing. Furthermore, the plurality of convex and concave surfaces in the light-exiting surface 1021 can also be configured at intervals to satisfy continuous and smooth requirements.

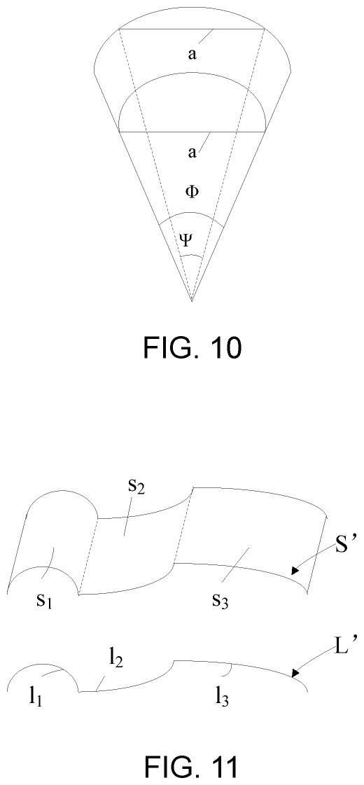

It should be noted that as shown in FIG. 10, for a same central angle Φ, the larger the corresponding circle radius is, the longer the arc formed is, which means that the curvature is smaller. When a chord length is a certain value a, the central angle of the circle with a smaller radius in the figure is still Φ, and the central angle of the circle with a larger radius is Ψ. Obviously, Ψ is smaller than Φ, which means that the central angle of the circle corresponding to the curved surface with a small curvature becomes smaller.

Understandably, after a length of the light extraction layer 102 is determined, the larger the curvature of the curved surface corresponding to the light-exiting surface 1021 is, the larger the central angle of the corresponding circle is, so that a range of directions of light that can be extracted from the light-emitting layer 101 becomes greater.

In contrast, comparing a premise that the light-emitting layer 101 emits light in various directions to the former case, the smaller the curvature of the curved surface corresponding to the light-exiting surface 1021 is, the larger an amount of light extracted from the light-emitting layer 101 in the direction corresponding to the curvature.

In an embodiment, as shown in FIG. 8, the light-exiting surface 1021 includes a plurality of convex surfaces and concave surfaces. The plurality of convex surfaces S3, S4, and S5 are upper hemispherical surfaces. The plurality of concave surfaces S6 and S7 are lower hemispherical surfaces. Radiuses of spheres corresponding to the upper hemispherical surfaces S3, S4, and S5 can be same or different. Radiuses of spheres corresponding to the lower hemispherical surfaces S6 and S7 can be same or different. For example, the radiuses of the spheres corresponding to the upper hemispherical surfaces S3 and S5 are same, and the radius of the sphere corresponding to the upper hemispherical surfaces S4 is greater than the radiuses of the spheres corresponding to the upper hemispherical surfaces S3 and S5, or the radiuses of the spheres corresponding to the lower hemispherical surfaces S6 and S7 are same.

In an embodiment, highest points of the curved surfaces corresponding to the light-exiting surface 1021 can be located on a same horizontal plane, and lowest points of the curved surfaces can be located on a same horizontal plane. Understandably, this can ensure that the light emitted from the light-emitting layer 101 on the light-exiting surface 1021 is within a preset height range to increase uniformity of refracted light corresponding to the light. Furthermore, when the light-exiting surface 1021 includes the plurality of convex surfaces and concave surfaces, the curvature and a vertical height between the highest point and the lowest point can be balanced according to an actual situation to obtain proper uniformity and light extraction range.

For example, highest points of the convex curved surfaces S1 and S2 in the embodiment of FIG. 7 are located on a same horizontal plane, but not limited to specific positions of the highest points of the convex curved surfaces S1 and S2 on the same horizontal plane. Similarly, lowest points of the concave curved surfaces in the embodiment of FIG. 7 are located on a same horizontal plane, but not limited to specific positions of the lowest points of the concave curved surfaces on the same horizontal plane.

For another example, highest points of the upper hemispherical surfaces S3, S4, and S5 in the embodiment of FIG. 8 are located on a same horizontal plane, but not limited to specific positions of the highest points of the upper hemispherical surfaces S3, S4, and S5 on the same horizontal plane, which means that the radiuses of the spheres corresponding to the upper hemispherical surfaces S3, S4, and S5 are not limited herein. Similarly, lowest points of the lower hemispherical surfaces S6 and S7 in the embodiment of FIG. 8 are located on a same horizontal plane, but not limited to specific positions of the lowest points of the lower hemispherical surfaces S6 and S7 on the same horizontal plane, which means that the radiuses of the spheres corresponding to the lower hemispherical surfaces S6 and S7 are not limited herein.

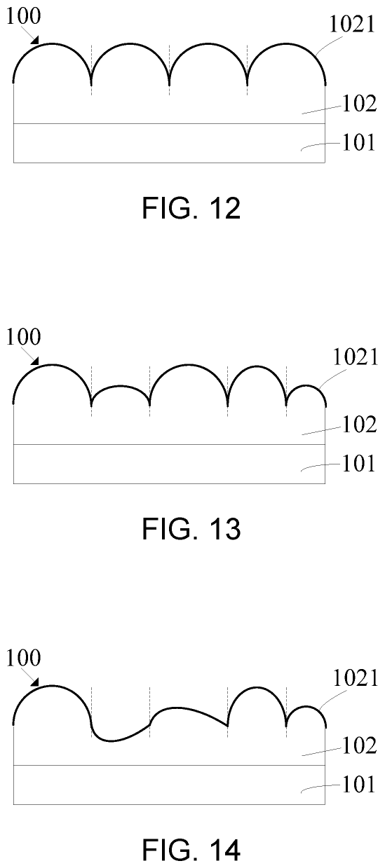

When the light-exiting surface 1021 includes the plurality of curved surfaces, understandably, as shown in FIG. 11, the light-exiting surface 1021 can be a trajectory S′ formed by a continuous and smooth combination curve L′ formed by a plurality of continuous and smooth curves I₁, I₂, and I₃ in a plane continuously moving in space. A junction between the smooth curves I₁ and I₂ is not smooth, which means that slopes on two sides of the junction between the curves I₁ and I₂ are not equal. A junction between the smooth curves I₂ and I₃ is not smooth as well. The trajectory S′ includes trajectories s₁, s₂, and s₃ formed by a continuous movement of the curves I₁, I₂, and I₃ in space, respectively. For ease of understanding, it can be assumed here that the continuous and smooth curve L′ is a curve formed by cutting the light-exiting surface 1021 of the light extraction layer 102 in a direction parallel to a length of the display panel 100. Understandably, the direction of the movement is a direction parallel to a width of the display panel 100. For specific embodiments, please refer to FIGS. 12 to 14. Of course, the direction of the movement herein may not be limited to one direction, which means that the direction of the movement can include multiple directions.

It should be noted that whether the light-exiting surface 1021 includes a curved surface or a plurality of curved surfaces is determined according to whether any point on the light-exiting surface 1021 has a same slope in any direction. If so, then it is the former; otherwise, it is the latter.

In an embodiment, as shown in FIGS. 12 to 14, when the light-exiting surface 1021 includes a plurality of curved surfaces, the plurality of curved surfaces are connected to each other and form a continuous light-exiting surface 1021.

In an embodiment, as shown in FIG. 12, the light-exiting surface 1021 can be formed by connecting a plurality of same convex curved surfaces. Furthermore, the plurality of same convex curved surfaces can be the upper hemispherical surfaces or can be non-upper hemispherical surfaces with same or different curvatures. Similarly, the light-exiting surface 1021 can be formed by connecting a plurality of same concave curved surfaces. For related descriptions, please refer to the above description of the plurality of same convex curved surfaces.

In an embodiment, as shown in FIG. 13, the light-exiting surface 1021 can be formed by connecting a plurality of different convex curved surfaces. The plurality of different convex curved surfaces can include the upper hemispherical surfaces with same or different curvatures and can include convex curved surfaces of non-upper hemispherical surfaces with same or different curvatures. The light-exiting surface 1021 can be formed by connecting a plurality of different convex curved surfaces and a plurality of same convex curved surfaces. For related descriptions of the plurality of convex curved surfaces, please refer to the above description.

In an embodiment, as shown in FIG. 14, the light-exiting surface 1021 can be formed by connecting the plurality of convex curved surfaces and the plurality of concave curved surfaces. The plurality of convex curved surfaces can include the upper hemispherical surfaces with same or different curvatures and can include convex curved surfaces of non-upper hemispherical surfaces with curvatures including at least one value. Similarly, for related descriptions of the plurality of concave curved surfaces, please refer to the above description of the plurality of convex curved surfaces.

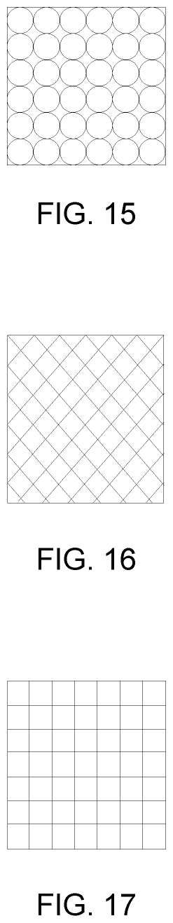

In an embodiment, as shown in FIGS. 15 to 17, a shape of a projection of the curved surface corresponding to the light-exiting surface 1021 in the light extraction layer 102 includes, but is not limited to, circular, rhombic, or square. Furthermore, the shape of the projection can be, but is not limited to, circular, rhombic, or square arranged in an array, and patterns of the array can also be different.

In an embodiment, material of the light extraction layer 102 includes a nano material.

In an embodiment, a thickness of the light extraction layer 102 is not less than 2 nanometers and not greater than 20 nanometers.

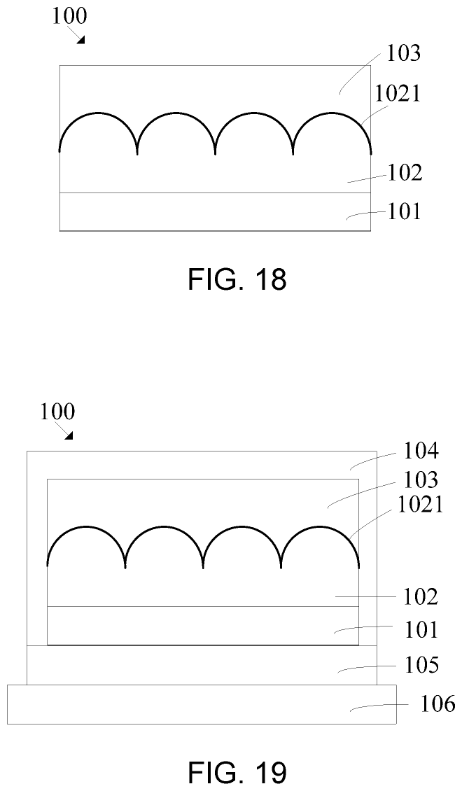

In an embodiment, as shown in FIG. 18, the display panel 100 further includes a protective layer 103. The protective layer 103 is disposed on a side of the light extraction layer 102 away from the light-emitting layer 101. Material of the protective layer 103 includes lithium fluoride.

In an embodiment, a refractive index of the light extraction layer 102 is greater than a refractive index of the protective layer 103.

In an embodiment, as shown in FIG. 19, the display panel 100 can further include a packaging layer 104, a thin-film transistor layer 105, and a substrate 106.

The thin-film transistor layer 105 is disposed on a side of the light-emitting layer 101 away from the light extraction layer 102 and is configured to provide an operating voltage to the light-emitting layer 101. The substrate 106 is disposed on a side of the thin-film transistor layer 105 away from the light-emitting layer 101 and is configured to support the display panel 100. The packaging layer 104 is disposed on a side of the protective layer 103 and the thin-film transistor layer 105 away from the substrate 106, and is configured to fix and protect the light-emitting layer 101, the light extraction layer 102, and the protective layer 103.

The present invention provides the display panel and the display device, including the light-emitting layer and the light extraction layer disposed on the side of the light-emitting layer. The light-exiting surface is disposed on the side of the light extraction layer away from the light-emitting layer. By disposing at least one curved surface on the light-exiting surface and determining a proper curvature of the at least one curved surface, the light emitted from the light-emitting layer in most directions can be prevented from being totally reflected on the light-exiting surface, which increases light utilization of an organic light-emitting diode (OLED) display panel to improve image quality of the OLED display panel.

The display panel and the display device including the display panel provided by embodiments of the present invention are described in detail above. The description of embodiments above is only for helping to understand technical solutions of the present invention and its core idea. Understandably, for a person of ordinary skill in the art can make various modifications of the technical solutions of the embodiments of the present invention above. However, it does not depart from the scope of the technical solutions of the embodiments of the present invention.

What is claimed is:

1. A display panel, comprising:
a light-emitting layer configured to emit light; and
a light extraction layer disposed on a side of the light-emitting layer and configured to transmit the light, wherein the light extraction layer comprises:
a light-exiting surface disposed on a side of the light extraction layer away from the light-emitting layer, wherein the light-exiting surface comprises at least one curved surface, and the light is refracted by the light-exiting surface.

2. The display panel as claimed in claim 1, wherein when the light-exiting surface comprises a plurality of curved surfaces, the plurality of curved surfaces are connected to each other and form a continuous light-exiting surface.

3. The display panel as claimed in claim 2, wherein highest points of the plurality of curved surfaces are on a same horizontal plane, and lowest points of the plurality of curved surfaces are on a same horizontal plane.

4. The display panel as claimed in claim 2, wherein shapes of the plurality of curved surfaces are same or different.

5. The display panel as claimed in claim 4, wherein the shapes of the plurality of curved surfaces comprise at least one of an upper hemispherical surface or a lower hemispherical surface.

6. The display panel as claimed in claim 1, wherein a shape of a projection of the at least one curved surface on the light extraction layer comprises circular, rhombic, or square.

7. The display panel as claimed in claim 1, wherein material of the light extraction layer comprises a nano material.

8. The display panel as claimed in claim 1, wherein a thickness of the light extraction layer is not less than 2 nanometers and not greater than 20 nanometers.

9. The display panel as claimed in claim 1, further comprising a protective layer disposed on the side of the light extraction layer away from the light-emitting layer, wherein material of the protective layer comprises lithium fluoride.

10. The display panel as claimed in claim 9, wherein a refractive index of the light extraction layer is greater than a refractive index of the protective layer.

11. A display device, comprising a display panel;
wherein the display panel comprises:
a light-emitting layer configured to emit light; and
a light extraction layer disposed on a side of the light-emitting layer and configured to transmit the light, wherein the light extraction layer comprises:
a light-exiting surface disposed on a side of the light extraction layer away from the light-emitting layer, wherein the light-exiting surface comprises at least one curved surface, and the light is refracted by the light-exiting surface.

12. The display device as claimed in claim 11, wherein when the light-exiting surface comprises a plurality of curved surfaces, the plurality of curved surfaces are connected to each other and form a continuous light-exiting surface.

13. The display device as claimed in claim 12, wherein highest points of the plurality of curved surfaces are on a same horizontal plane, and lowest points of the plurality of curved surfaces are on a same horizontal plane.

14. The display device as claimed in claim 12, wherein shapes of the plurality of curved surfaces are same or different.

15. The display device as claimed in claim 14, wherein the shapes of the plurality of curved surfaces comprise at least one of an upper hemispherical surface or a lower hemispherical surface.

16. The display device as claimed in claim 11, wherein a shape of a projection of the at least one curved surface on the light extraction layer comprises circular, rhombic, or square.

17. The display device as claimed in claim 11, wherein material of the light extraction layer comprises a nano material.

18. The display device as claimed in claim 11, wherein a thickness of the light extraction layer is not less than 2 nanometers and not greater than 20 nanometers.

19. The display device as claimed in claim 11, further comprising a protective layer disposed on the side of the light extraction layer away from the light-emitting layer, wherein material of the protective layer comprises lithium fluoride.

20. The display device as claimed in claim 19, wherein a refractive index of the light extraction layer is greater than a refractive index of the protective layer.
